(19) United States
(12) Patent Application Publication
(10) Pub. No.: US 2009/0085039 A1
(43) Pub. Date: Apr. 2, 2009

(54) Image display system and fabrication method thereof

(75) Inventors: Ming-Yu Chung, Hsinchu City (TW); Shan-Hung Tsai, Taichung City (TW); Su-Fen Chen, Jhunan Township (TW); Kuan-Shiang Wong, Jhubei City (TW); Hsiao-Po Chang, Jhunan Township (TW); Jung-Huang Chien, Dasi Township (TW); Hsiu-Hsiu Chen, Tongsiao Township (TW)

Correspondence Address: LIU & LIU, 444 S. FLOWER STREET, SUITE 1750, LOS ANGELES, CA, 90071, US

(73) Assignee: TPO Displays Corp.

(21) Appl. No.: 12/284,581

(22) Filed: Sep. 22, 2008

Related U.S. Application Data
(60) Provisional application No. 60/975,821, filed on Sep. 28, 2007.
(60) Provisional application No. 60/982,421, filed on Oct. 25, 2007.

(30) Foreign Application Priority Data
Mar. 18, 2008 (TW) 097109450

(51) Int. Cl. H01L 21/336; H01L 33/00

(52) U.S. Cl. 257/72; 438/38; 257/E33.003; 257/E21.412

(57) ABSTRACT

The invention provides a method for fabricating a low-temperature polysilicon (LTPS) driving circuit and thin film transistor. The method includes: providing a substrate, forming an active layer, forming a gate insulating layer, forming a dielectric layer having an extending portion and forming a gate electrode. The extending portion of the dielectric layer and the gate electrode are formed during the same step, and they can serve as a mask during a later doping process so that a lightly doped source/drain region and a source/drain region are formed during the same time without forming extra masks.

### CROSS REFERENCE TO RELATED APPLICATIONS

This application claims the benefit of U.S. Provisional Application No. 60/975,821, filed on Sep. 28, 2007, U.S. Provisional Application No. 60/982,421, filed on Oct. 25, 2007 and Taiwan Patent Application No. 097109450, filed on Mar. 18, 2008.

### BACKGROUND OF THE INVENTION

1. Field of the Invention

The invention relates to image display devices, and more particularly to a display panel using a low-temperature polysilicon (LTPS) driving circuit and thin film transistor (TFT) and a fabrication method thereof.

2. Description of the Related Art

In general, a thin film transistor (TFT) may be classified as an amorphous thin film transistor or a polysilicon thin film transistor. The polysilicon thin film transistor is fabricated by using a low-temperature polysilicon (LTPS) technique, and is different from fabrication of the amorphous thin film transistor using an amorphous silicon (a-Si) technique. The LTPS transistor has relatively greater electron mobility (>200 cm²/V-sec) and hence the LTPS transistor can have a smaller dimension, a larger aperture ratio and a lower power requirement. In addition, the LTPS process also permits concurrent fabrication of the driving circuit and the thin film transistor on the same substrate, so that a display panel that is formed has greater reliability and lower production costs.

For conventional techniques, 8 or even 9 masks are required to fabricate the LTPS driving circuit and thin film transistor, resulting in higher production costs. In addition, as each mask is added to the fabrication process, the additional results in an increase in production time and lower production yield.

Thus, an LTPS technique using a smaller number of masks to reduce production costs is needed.

### BRIEF SUMMARY OF INVENTION

Accordingly, the invention provides an exemplary embodiment of an image display system, including a low-temperature polysilicon (LTPS) driving circuit and thin film transistor (TFT). The LTPS driving circuit and thin film transistor includes: a substrate; an active layer formed over the substrate; a gate insulating layer covering the active layer; a dielectric layer having an extending portion disposed on the gate insulating layer; and a gate electrode formed on the dielectric layer, exposing the extending portion of the dielectric layer. Moreover, the system further includes: a storage capacity device, having an upper electrode and a lower electrode, formed over the substrate; a contact hole formed in the gate insulating layer, exposing a region where the lower electrode is adjacent to the active layer of the thin film transistor; and a plurality of wiring lines, which electrically connects to the driving circuit to the thin film transistor, and a pixel electrode, which is electrically connected to the thin film transistor, formed over the substrate. The extending portion of the dielectric layer is capable of decreasing the off-current (I_{off}) of the thin film transistor.

The invention provides an exemplary embodiment of a method for fabricating an image display system, which includes providing an LTPS driving circuit and thin film transistor. The method includes: providing a substrate; forming a first active layer and a second active layer over the substrate; performing a P+ doping process to form a source/drain region in the second active layer; forming a dielectric layer having an extending portion on the first active layer; forming a first gate electrode and a second gate electrode over the first active layer and the second active layer; and performing an N+ doping process to simultaneously form a lightly doped source/drain region and a source/drain region in the first active layer. Moreover, the method further includes: forming a plurality of wiring lines over the substrate to electrically connect the driving circuit to the thin film transistor; and forming a pixel electrode electrically connected to the thin film transistor over the substrate. In addition, the first and the second gate electrodes and the dielectric layer having the extending portion are formed during the same step, by depositing a dielectric material layer and a metal layer, and then patterning the metal layer and the dielectric material layer.

Since the dielectric layer having the extending portion is formed during the same step as the gate electrodes without extra masks, number of masks used in fabrication process is decreased. Moreover, the gate electrodes and the extending portion of the dielectric layer may act as a mask so that the N+ doping process can be performed with no mask, and by which the lightly doped source/drain region and the source/drain region can be simultaneously formed by a single doping process. Accordingly, number of masks used in fabrication process is decreased and production costs are hence reduced.

Also, the invention provides an exemplary embodiment of a method for fabricating an image display system, which includes providing an LTPS driving circuit and thin film transistor. The method includes: providing a substrate; forming a first active layer and a second active layer over the substrate; forming a dielectric layer having an extending portion on the first active layer; forming a first gate electrode and a second gate electrode over the first active layer and the second active layer; and performing an N+ doping process to simultaneously form a lightly doped source/drain region and a source/drain region in the first active layer; and performing a P+ doping process to form a source/drain region in the second active layer. Moreover, the method further includes: and forming a plurality of wiring lines over the substrate to electrically connect the driving circuit to the thin film transistor; forming a pixel electrode electrically connected to the thin film transistor over the substrate. Furthermore, the first and the second gate electrodes and the extending portion of the dielectric layer are formed at the same steps, by depositing a dielectric material layer and a metal layer, and then patterning the metal layer and the dielectric material layer.

A detailed description is given in the following embodiments with reference to the accompanying drawings.

### BRIEF DESCRIPTION OF DRAWINGS

The invention can be more fully understood by reading the subsequent detailed description and examples with references made to the accompanying drawings, wherein:

FIGS. 1A to 1H are cross sections illustrating a method for fabricating a low-temperature polysilicon (LTPS) driving circuit and thin film transistor according to a first embodiment of the invention;

FIGS. 2A to 2G are cross sections illustrating a method for fabricating an LTPS driving circuit and thin film transistor according to a second embodiment of the invention;

FIG. 3 is a flowchart of a method for fabricating an LTPS driving circuit and thin film transistor according to the embodiments of the invention;

FIG. 4 is a schematic view of an image display system that includes a display panel composed of the LTPS driving circuit and thin film transistor according to the embodiments of the invention.

### DETAILED DESCRIPTION OF INVENTION

The following description is of the exemplary embodiments of carrying out the invention. This description is made for the purpose of illustrating the general principles of the invention and should not be taken in a limiting sense. The scope of the invention is best determined by reference to the appended claims.

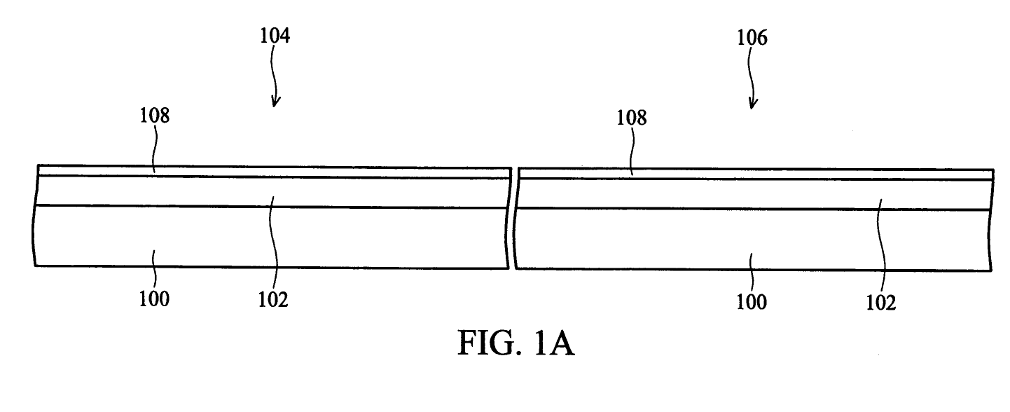

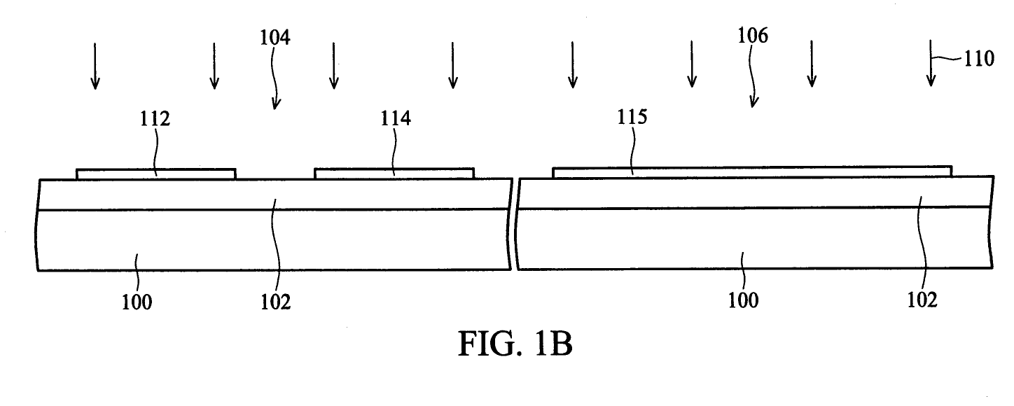

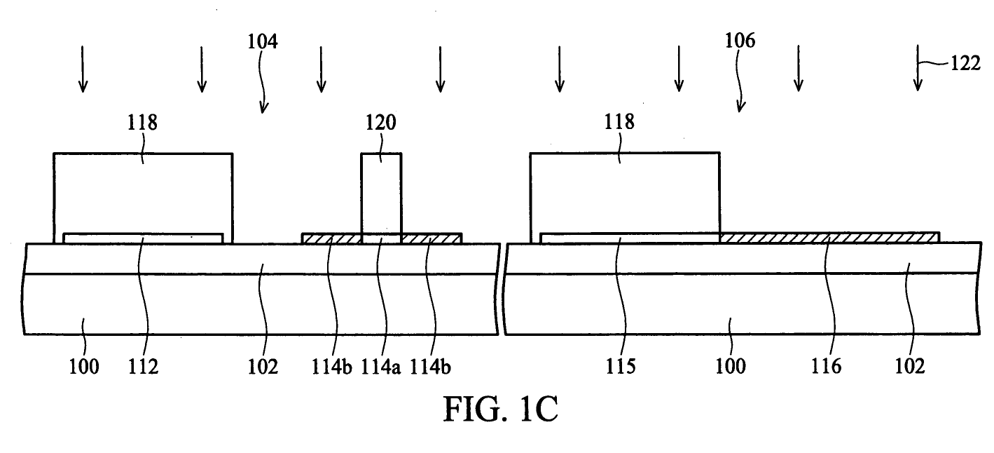

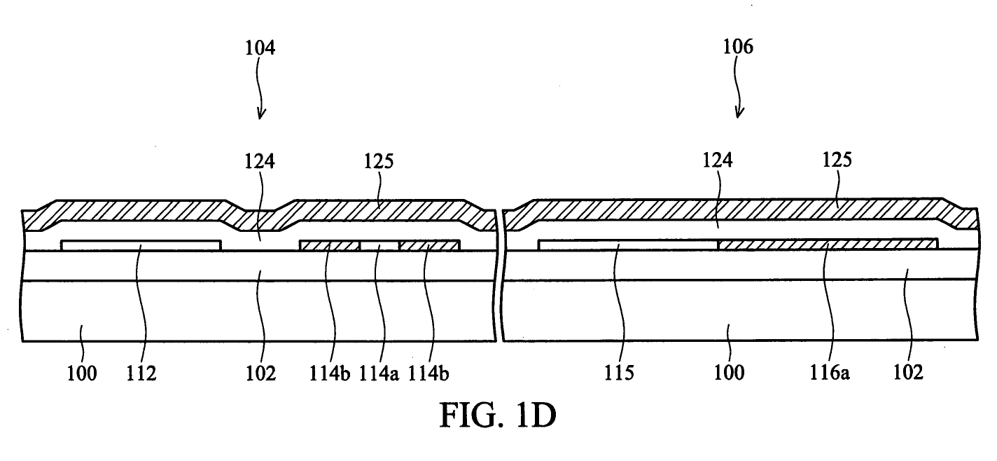

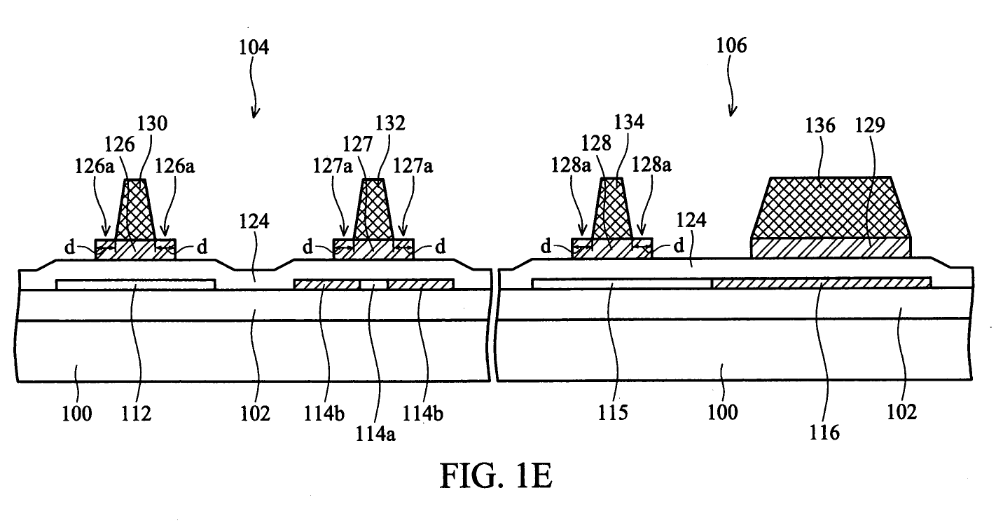

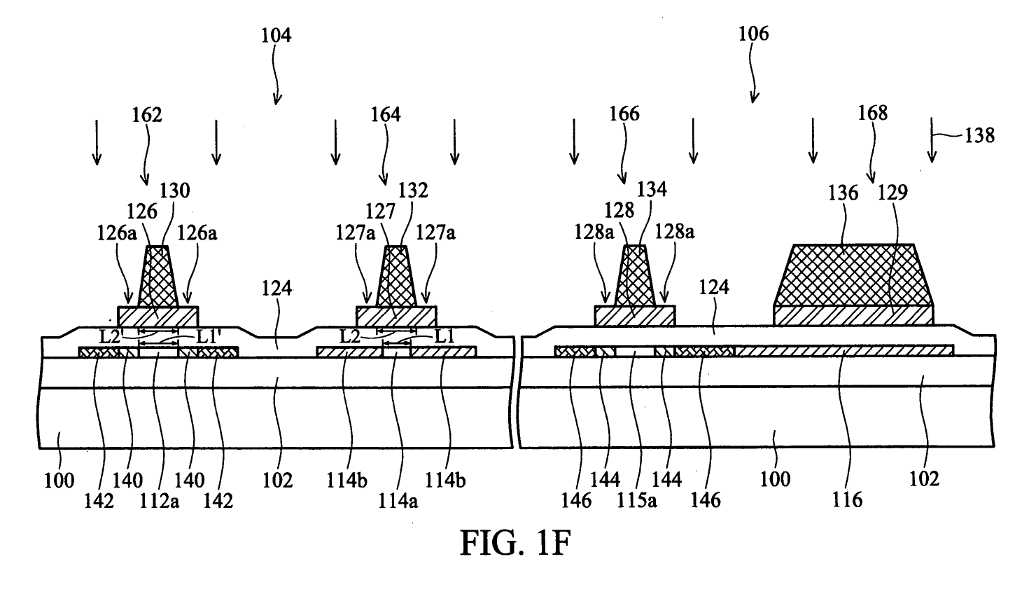

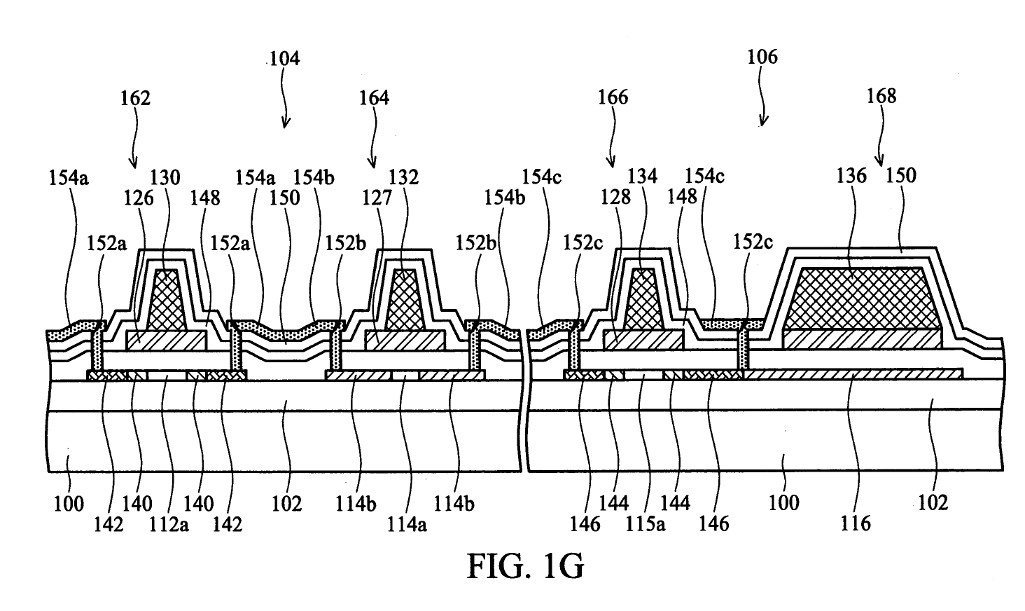

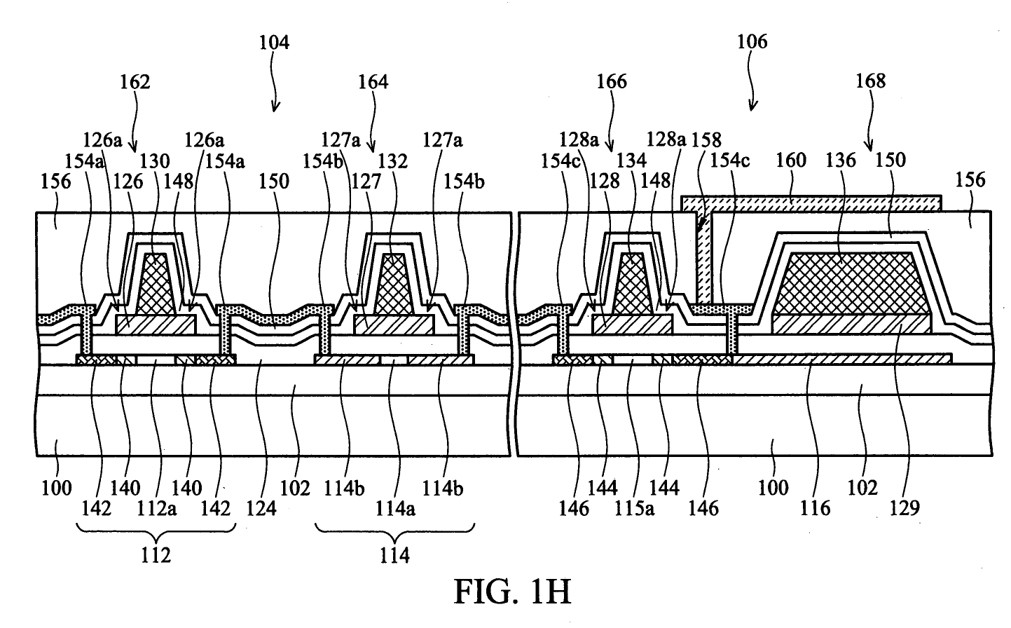

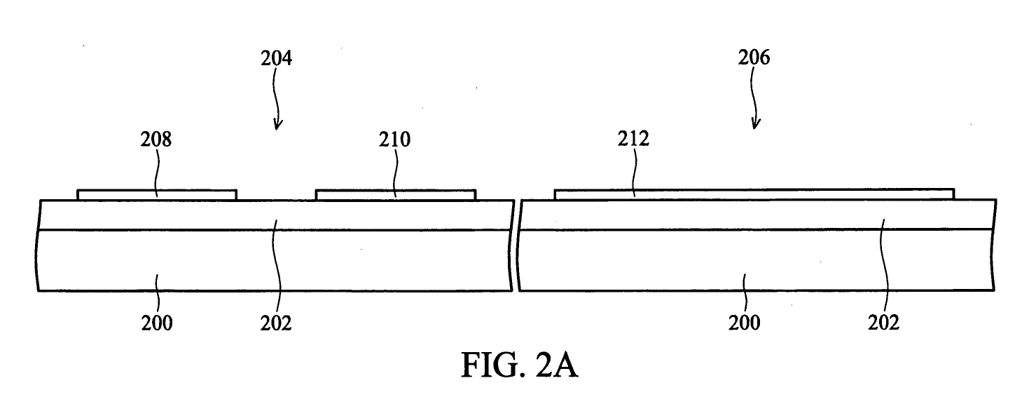

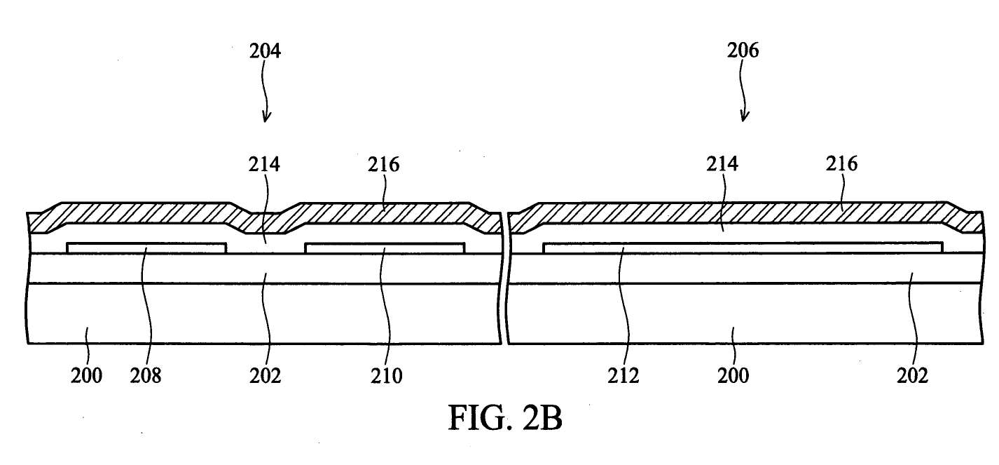

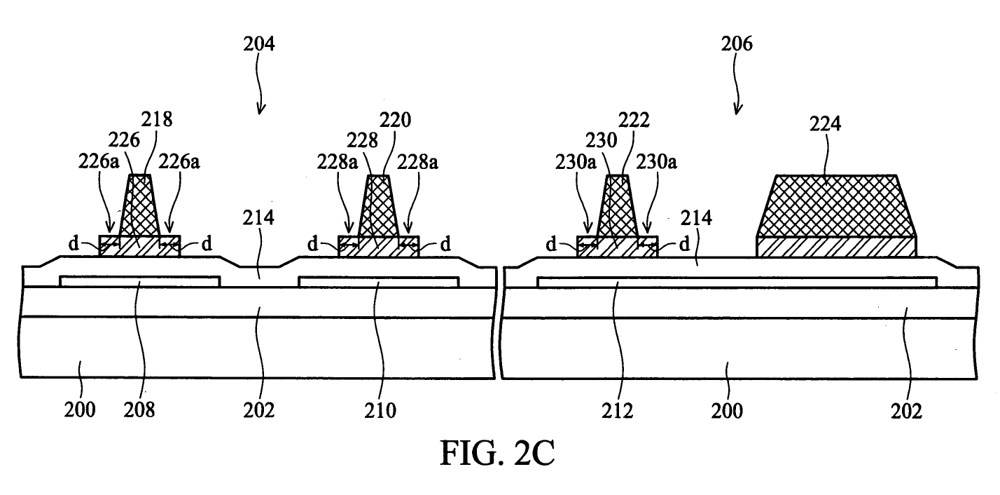

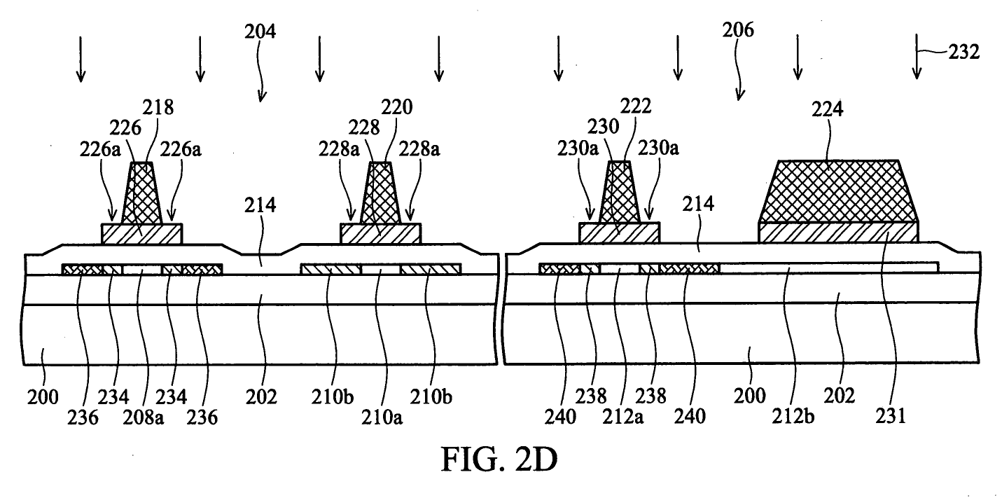

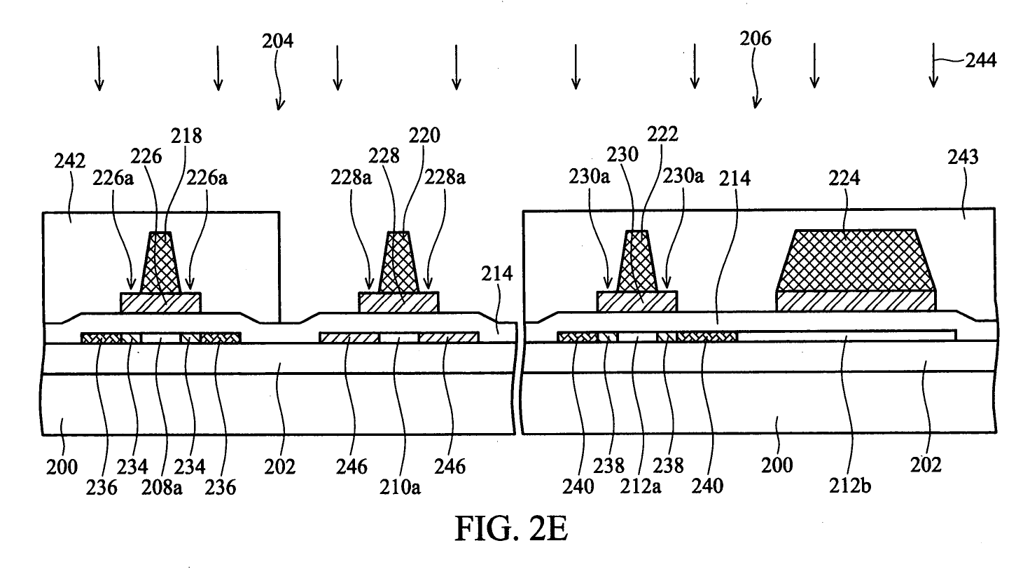

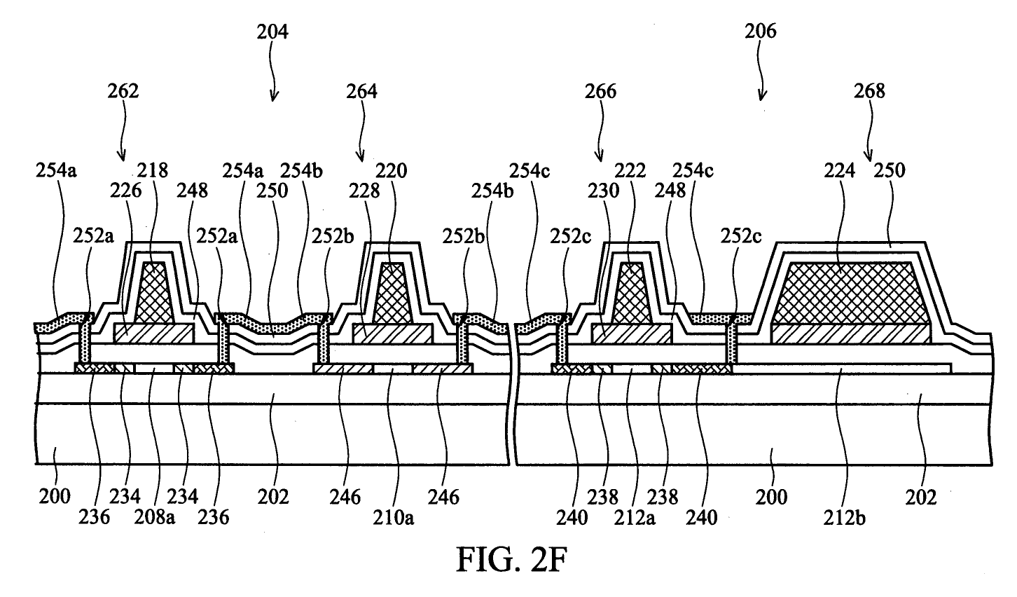

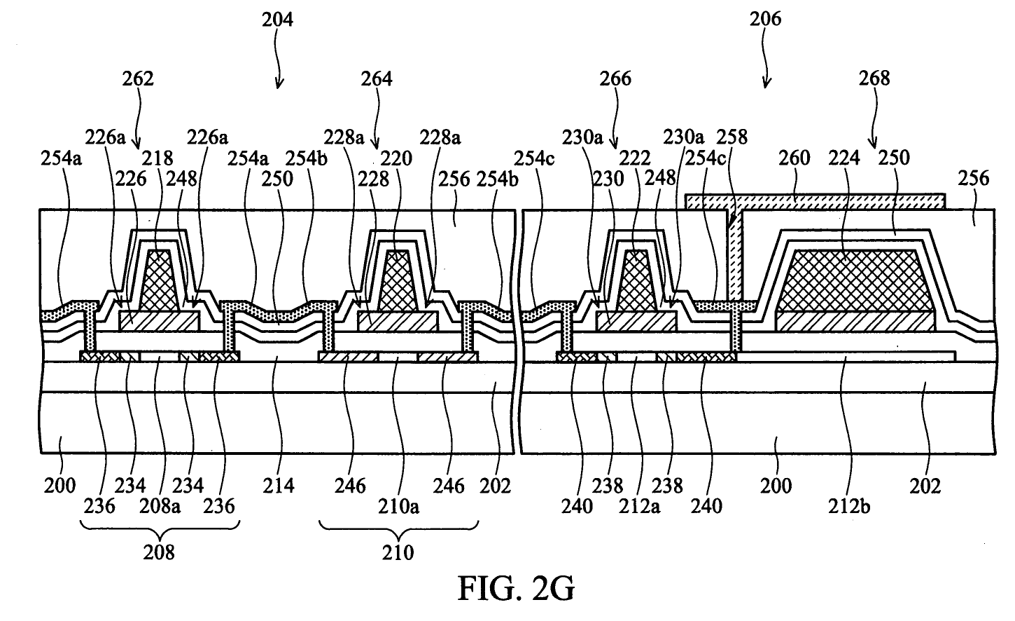

The invention will be described with respect to the exemplary embodiments in a specific context, namely a method for fabricating a low-temperature polysilicon (LTPS) driving circuit and thin film transistor (TFT). The invention may also be applied, however, to fabricating other integrated circuits. FIGS. 1A to 1H are cross sections illustrating a method for fabricating an LTPS driving circuit and thin film transistor according to a first embodiment of the invention. FIGS. 2A to 2G are cross sections illustrating a method for fabricating an LTPS driving circuit and thin film transistor according to a second embodiment of the invention.

Referring to FIG. 1, a substrate 100, divided into a driving area 104 and a pixel area 106, is provided with a buffer layer 102 formed thereon. The substrate 100 can be made of a material such as glass, plastic or other suitable transparent materials.

Next, a semiconductor layer 108, such as polysilicon, is formed over the substrate 100. In some embodiments, an amorphous silicon (a-Si) layer is deposited over the substrate 100 by a chemical vapor deposition (CVD) process, followed by carrying out an excimer laser annealing (ELA) process so that the amorphous silicon layer crystallizes into a polysilicon layer.

Referring to FIG. 1B, the semiconductor layer 108 is patterned, and a doping process is then carried out to form active layers 112 and 114 and a doped semiconductor layer 115. Moreover, a portion of the doped semiconductor layer 115, which is located at the pixel area 106, may serve as an active layer of a thin film transistor later formed. In addition, the doping process may also be carried out prior to patterning the semiconductor layer.

In one embodiment, the semiconductor layer 108 may also be formed by depositing the amorphous silicon layer accompanied by a doping process, and then carrying out an ELA process to crystallize the amorphous silicon layer into a polysilicon layer, and finally carrying out patterning of the polysilicon layer. Moreover, the doping process may also be referred to as a channel doping process.

Referring to FIG. 1C, a P+ doping process 122, implanting dopants such as boron ions, is carried out to form a source/drain region 114b in the active layer 114. In some embodiments, a photoresist material is coated to cover the substrate 100, followed by patterning to form patterned photoresist layers 118 and 120. For the driving circuit area 104, the patterned photoresist layer 118 masks the active layer 112, and the patterned photoresist layer 120 masks a portion of the active layer 114 to expose an intended region for doping. For the pixel area 106, the patterned photoresist layer 118 masks a portion of the doped semiconductor layer 115 to expose an intended region for doping. Next, when the doping process 122 has been carried out, the source/drain region 114b and the channel region 114a are formed. Meanwhile, a lower electrode 116 of a storage capacity device is formed at the pixel area 106. After the doping process 122 has been completed, the patterned photoresist layers 118 and 120 are removed.

Referring to FIG. 1D, a gate insulating layer 124 and a dielectric material layer 125 are sequentially formed over the substrate 100, and cover the above-fabricated elements. The dielectric material layer 125 can be made of a material such as silicon nitride, silicon oxynitride, or other suitable nitride-based materials, and the gate insulating layer 124 can be made of a material such as silicon oxide. Moreover, the dielectric material layer 125 has a thickness relating to the implantation energy of an N+ doping process that is subsequently performed. The thickness of the dielectric material layer 125 can be, but is not limited to, about 400 angstrom (Å).

In another embodiment, the P+ doping process 122 may be carried out after the gate electrode 124 or the dielectric material layer 125 are formed to form the source/drain region 114b in the active layer 114.

Referring to FIG. 1E, the gates electrodes 130, 132 and 134 and an upper electrode 136 is respectively formed on the dielectric layers 126, 127, 128, and 129. In one embodiment, a metal layer, such as an aluminum/molybdenum alloy (Al/Mo), is formed over the substrate 100 and a patterned photoresist layer (not shown) is then formed thereon. Next, a portion of the metal layer and a portion of the dielectric material layer are removed by a concurrent process such as an over-etching step. Thereafter, the patterned photoresist layer is removed, simultaneously forming the gate electrodes 130, 132, 134 and the upper electrode 136, and the dielectric layers 126, 127, 128 and 129.

Moreover, during the over-etching step to the metal layer, the extending portions 126a, 127a and 128a of the dielectric layers 126, 127 and 128 can also be formed, without requirement for extra masks because the gate electrodes can serve as a mask. Accordingly, fabrication processes are decreased. The extending portions 126a, 127a and 128a of the dielectric layers 126, 127 and 128 have a length d, but are not limited, of about 3000 to 5000 angstrom (Å).

Referring to FIG. 1F, an N+ doping process 138, implanting dopants such as phosphor ions, is carried out to simultaneously form lightly doped source/drain regions 140 and 144, and source/drain regions 142 and 146. Note that the N+ doping process 138 is carried out after the formation of the gate electrodes 130, 132 and 134 so that the gate electrodes 130, 132 and 134 can act as a mask for the channel regions 112a, 114a and 115a during the N+ doping process.

In addition, the extending portion 126a of the dielectric layer 126 and the extending portion 128a of the dielectric layer 128 may act as a mask reducing phosphor ions, which pass through during the N+ doping process. Accordingly, a portion of the active layers 112 and 115, covered by the extending portions 126a and 128a, has the doped concentration of phosphor ions smaller than the doped concentration of phosphor ions of the other active layers 112 and 115, uncovered by the extending portions 126a and 128a. The gate electrodes and the extending portions of the dielectric layers may act as a mask so that the N+ doping process can be directly carried out without extra steps for forming masks, and by which the lightly doped source/drain regions and source/drain regions can be simultaneously formed.

Since the extending portions 126a and 128a may act as a mask during the N+ doping process, the sidewalls of the lightly doped source/drain regions 140 and 144 are aligned with the sidewalls of the extending portions 126a and 128a. Moreover, the extending portions of the dielectric layers and the gate electrodes may be in situ formed without extra masks, and they can serve as a mask during the doping process so that the lightly doped source/drain regions and the source/drain regions can be simultaneously formed with no mask. Hence, the method for fabricating the LTPS driving circuit and thin film transistor according to the first embodiment of the invention decreases at least two masks when compared with conventional methods. Accordingly, fabrication process is shortened and production costs are reduced.

When the above-described steps have been completed, an N-type metal-oxide semiconductor (NMOS) device 162, composed of the channel region 112a, the lightly doped source/drain region 140, the source/drain region 142, the gate insulating layer 1,24, the dielectric layer 126 and the gate electrode 130, is formed at the driving circuit area 104. A P-type metal-oxide semiconductor (PMOS) device 164, composed of the channel region 114a, the source/drain region 114b, the gate insulating layer 124, the dielectric layer 127 and the gate electrode 132, is formed at the driving circuit area 104. Also, a thin film transistor (TFT) 166, composed of the channel region 115a, the lightly doped source/drain region 144, the source/drain region 146, the gate insulating layer 124, the dielectric layer 128 and the gate electrode 134, and a storage capacity device 168 are formed at the pixel area 106.

Note that in order to completely cover the channel region 114a during the N+ doping process, the gate electrode 132 of the PMOS device 164 preferably has a bottom width L2 larger than the length L1 of the channel region 114a of the PMOS device 164. In an exemplary embodiment, the length L1 of the channel region 114a is similar to the length L1′ of the channel region 112a, and the gate electrode 132 of the PMOS device 164 has the bottom width L2 larger than the bottom width L2′ of the gate electrode 132 of the NMOS device 162. Alternatively, in an exemplary embodiment, the bottom width L2 of the gate electrode 132 is similar to the bottom width L2′ of the gate electrode 130, and the channel region 114a of the PMOS device 164 has a length L1 smaller than the length L1′ of the channel region 112a of the NMOS device 162.

Referring to FIG. 1G, an interlayer dielectric 148 and a passivation layer 150 are sequentially deposited over the substrate 100, followed by patterning to form contact holes 152a, 152b, and 152c in the interlayer dielectric 148 and the passivation layer 150, and expose the source/drain regions 142, 114b and 146.

In FIG. 1G, after the interlayer dielectric 148 and the passivation layer 150 have been formed, wiring lines 154a, 154b, and 154c are formed in the contact holes 152a, 152b, and 152c. In some embodiments, a metal stack of molybdenum, aluminum and molybdenum (Mo/Al/Mo) covers the substrate 100, and is then patterned to form the wiring lines 154a, 154b and 154c, and by which the thin film transistor 166 of the pixel area 106 is electrically connected to the driving circuit of the driving circuit area 104.

Note that according to the first embodiment of the invention, the lower electrode 116 of the storage capacity device 168 is doped with P-type dopants, and the source/drain region 146 of the thin film transistor 166 is doped with N-type dopants at the pixel area 106. Thus, therebetween, a PN junction occurs. The contact hole 152c can be formed at a region where the lower electrode 116 is adjacent or next to the source/drain region 146, and then filled with the wiring line 154c for electron and hole transmissions, thus, the PN junction is eliminated.

Referring to FIG. 1H, an overcoating layer 156 is blanketly formed over the substrate 100, and then patterned to form an opening 158. Next, a pixel electrode 160 is formed on the overcoating layer 156, and passes through the opening 158 to electrically connect to the source/drain region 146 of the thin film transistor 166. In one embodiment, a transparent conductive layer, which is made of indium tin oxide (ITO), is formed over the substrate 100, and then patterned to form the pixel electrode 160.

In FIG. 1H, a cross section of an LTPS driving circuit and thin film transistor according to the first embodiment of the invention is shown. Referring to FIG. 1H, a complementary metal-oxide semiconductor (CMOS) device, composed of the NMOS device 162 and the PMOS device 164, is formed at the driving circuit area 104. The NMOS device 162 includes the active layer 112, the gate insulating layer 124, the dielectric layer 126 having the extending portion 126a and the gate electrode 130, in which the gate electrode 130 is located on the dielectric layer 126 and exposes the extending portion 126a. The PMOS device 164 includes the active layer 114 having the channel region 114a and the source/drain region 114b, the gate insulating layer 124 and the gate electrode 132, in which the gate electrode 132 has a bottom width larger than the length of the channel region 114a.

As shown in FIG. 1H, the thin film transistor 166 and the storage capacity device 168 are formed at the pixel area 106. The thin film transistor 166 includes the active layer, the gate insulating layer 124, the dielectric layer 128 having the extending portion 128a and the gate electrode 134, in which the gate electrode 134 is located on the dielectric layer 126 and exposes the extending portion 128a. The active layer includes the channel region 115a, the lightly doped source/drain region 144 and the source/drain region 146, in which the lightly doped source/drain region 144 has sidewalls aligned with the sidewalls of the extending portion 128a. In FIG. 1H, the wiring lines 154a, 154b, and 154c are formed over the substrate 100 and electrically connects the thin film transistor 166 to the driving circuit. The wiring line 154c passes through the contact hole to be in contact with the lower electrode 116 of the storage capacity device 168 and the source/drain region 146. Moreover, the pixel electrode 160 corresponding to the storage capacity device 168 is electrically connected to the thin film transistor 166.

Note that since the extending portions of the dielectric layers can act as a mask during the doping process and the extending portions are formed during the same step as the gate electrodes without extra masks, accordingly, the number of masks used in fabrication process can be decreased and production costs are also reduced. Moreover, by using the extending portion of the dielectric layer, off-current (I_{off}) of the thin film transistor can be reduced.

FIGS. 2A to 2G are cross sections illustrating a method for fabricating an LTPS driving circuit and thin film transistor according to a second embodiment of the invention. Compared with the first embodiment, the P+ doping process may be carried out after the gate electrode and the N+ doping process are completed. Repeated description of similar elements and formation and material thereof will not be provided hereafter, thus, references may be made to the descriptions in the first embodiment.

Referring to FIG. 2A, a substrate 200, divided into a driving area 204 and a pixel area 206, is provided with a buffer layer 202 formed thereon. Next, active layers 208 and 210 and a doped semiconductor layer 212 are formed over the substrate 200.

Referring to FIG. 2B, a gate insulating layer 214 and a dielectric material layer 216 are sequentially formed over the substrate 200, and cover the above-fabricated elements. In FIG. 2C, gate electrodes 218, 220, and 222 and dielectric layers 226, 228 and 230, which respectively have extending portions 226a, 228a and 230a, are formed over the substrate 200. Similar to the descriptions in the first embodiment, a metal layer is formed on the dielectric material layer 215, and a patterned photoresist material (not shown) is then formed thereon. By carrying out an over-etching process, the gate electrodes 218, 220 and 222 and the dielectric layer 226, 228 and 230 having the extending portions 226a, 228a and 230 are formed during the same time, rather than using extra masks. The extending portions 226a, 228a and 230a have a length d of about 3000 to 5000 angstrom (Å). When the above-described steps have been completed, a storage capacity device, composed of a lower electrode 212b (as shown in FIG. 2D) and an upper electrode 224, is formed at the pixel area 206 of the substrate 200. Since the extending portions of the dielectric layer and the gate electrode may be formed during the same step without using extra masks, the number of masks used in fabrication process is decreased and production costs are also reduced.

Referring to FIG. 2D, using the mask composed of the gate electrodes 218 and 222 and the extending portion 226a and 230a, an N+ doping process 232 is carried out to simultaneously form lightly doped source/drain regions 234 and 238, and source/drain regions 236 and 204, by which steps for forming extra masks are not required. Note that the lightly doped source/drain regions 234 and 238 have the sidewalls substantially aligned with the sidewalls of the extending portions 226a and 230a because of the extending portions 226a and 230a serving as a mask.

Referring to FIG. 2E, a P+ doping process 244 is carried out to form a source/drain region 246. In one embodiment, a photoresist material is deposited, and then patterned to form patterned photoresist layers 242 and 243 exposing an intended region for doping. Next, once the P+ doping process 244 has been carried out, the source/drain region 246 is formed. Note that since the N+ doping process is performed with no mask, the dopant concentration of the P+ doping process is preferably higher than the dopant concentration of the N+ doping process to make the N-type doped region 210b change into the P-type source/drain region 246.

Referring to FIG. 2F, an interlayer dielectric 248 and a passivation layer 250 are sequentially formed over the substrate 200, followed by patterning to form contact holes 252a, 252b, and 252c therein. Wiring lines 254a, 254b and 254c are formed over the substrate 200 and extend to the contact holes 252a, 252b and 252c to electrically connect the thin film transistor 266 to the COMS device, composed of the NMOS device 262 and the PMOS device 264. Note that the contact hole 252c exposes a region where the source/drain region 240 is adjacent to the lower electrode 212b so that the wiring line 254c can be in contact with the source/drain region 240 and the lower electrode 212b.

Referring to FIG. 2G, an overcoating layer 256 is formed over the substrate 200, followed by patterning to form an opening 258. Next, a pixel electrode 260, corresponding to the storage capacity device 268, is electrically connected to the thin film transistor 266.

FIG. 2G is a cross section of an LTPS driving circuit and thin film transistor according to the second embodiment of the invention. Referring to FIG. 2G, the CMOS device, composed of the NMOS device 262 and the PMOS device 264, is formed during the driving circuit 204. The NMOS device 262 includes the active layer 208, the gate insulating layer 214, the dielectric layer 226 having the extending portion 226a, and the gate electrode 218, in which the gate electrode 218 is located on the dielectric layer 226 and exposes the extending portion 226a. The PMOS device 264 includes the active layer 210, the gate insulating layer 214 and the gate electrode 220.

In FIG. 2G, the thin film transistor 266 and the storage capacity device 268 are formed at the pixel area 206. The thin film transistor 266 includes the active layer, composed of the channel region 212a, the lightly doped source/drain region 238 and the source/drain region 240, the gate insulating layer 214, the dielectric layer 230 having the extending portion 230a, and the gate electrode 222, in which the gate electrode 222 is disposed on the dielectric layer 230 and exposes the extending portion 230a, and the lightly doped source/drain region 238 has sidewalls substantially aligned with the sidewalls of the extending portion 230a. The storage capacity device 268, including the upper electrode 224 and the lower electrode 212b, is disposed over the substrate 200. As shown in FIG. 2G, the wiring lines 254a, 254b, and 254c are formed over the substrate 200 and electrically connect the thin film transistor 266 to the driving circuit. The pixel electrode 260, corresponding to the storage capacity device 268, is connected to the thin film transistor 266. Note that the wiring line 254c is in contact with the lower electrode 212b of the storage capacity device 268 and the source/drain region 240 of the thin film transistor 266 via the contact hole.

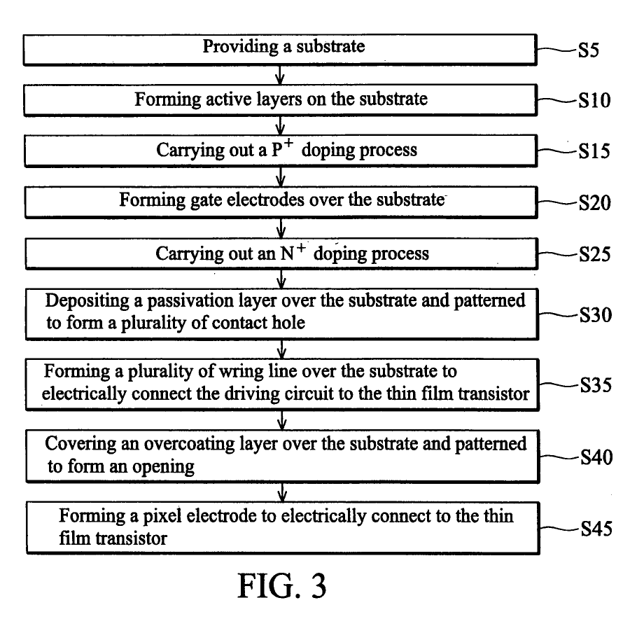

FIG. 3 is a flowchart of a method for fabricating an LTPS driving circuit and thin film transistor according to the embodiments of the invention. Referring to FIG. 3, a substrate is provided with active layers formed thereon (MASK 1), as shown in steps S5 and S10. A P+ doping process is locally carried out to form a source/drain region of a PMOS device (MASK 2), as shown in step S15. Gate electrodes are formed over the substrate (MASK 3), as shown in step S20. An N+ doping process is carried out with no mask to form lightly doped source/drain regions and source/drain regions of a NMOS and a thin film transistor at the same time (NO MASK), as shown in step S25. A passivation layer is deposited over the substrate, and then patterned to form a plurality of contact holes (MASK 4), as shown in step S30. A plurality of wiring lines is formed over the substrate to electrically connect the driving circuit to the thin film transistor (MASK 5), as shown in step S35. An overcoating layer is formed covering the substrate, and is then patterned to form an opening (MASK 6), as shown in step S40. A pixel electrode is formed to electrically connect to the thin film transistor (MASK 7), as shown in step S45.

Since the lightly doped source/drain region and the source/drain region can be simultaneously formed without masks during the N+ doping process, the number of masks used in fabrication process is decreased and production costs are hence reduced. Moreover, the step S15 shown in FIG. 3 may be carried out after the steps S20 and 25, as described in the second embodiment of the invention. For the description above, only 7 masks are required in the method for fabricating an LTPS driving circuit and thin film transistor according to the embodiments of the invention.

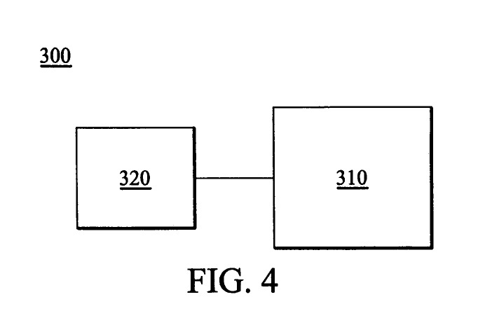

FIG. 4 is a schematic view of an image display system 300, in which a display panel 310, composed of an LTPS driving circuit and thin film transistor fabricated by the method according the embodiments of the invention, is utilized. Moreover, the display panel 310 may be a component of an electronic device. Referring to FIG. 4, the system 300 includes the display panel 310 and a control unit 320, which is coupled with the display panel 310. The system 300 may be electronic devices, such as mobile phones, digital cameras, personal digital assistants (PDA), notebook computers, desktop computers, televisions, automotive monitors, global positioning systems (GPS), avionics display or portable digital video disc (DVD) players.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An image display system, comprising:
a low-temperature polysilicon driving circuit and thin film transistor, comprising:
a substrate;
a first active layer formed over the substrate;
a gate insulating layer covering the first active layer;
a first dielectric layer having an extending portion and disposed on the gate insulating layer; and
a first gate electrode formed on the first dielectric layer, exposing the extending portion;
a storage capacity device having an upper electrode and a lower electrode and formed over the substrate;
a contact hole formed in the gate insulating layer, exposing a region where the lower electrode is adjacent to the first active layer;
a plurality of wiring lines formed over the substrate and electrically connecting the driving circuit to the thin film transistor; and
a pixel electrode electrically connected to the thin film transistor.

2. The system as claimed in claim 1, wherein the first active layer comprises:
a first channel region corresponding to the first gate electrode;
a first lightly doped source/drain region adjacent to the first channel region; and
a first source/drain region adjacent to the first lightly doped source/drain region.

3. The system as claimed in claim 2, wherein the driving circuit further comprises:
a second active layer having a second channel region and a second source/drain region adjacent to the second channel region therein, and formed on the substrate;
a second dielectric layer formed on the gate insulating layer; and
a second gate electrode corresponding to the second channel region and formed on the second dielectric layer.

4. The system as claimed in claim 3, wherein the second gate electrode has a bottom width larger than a length of the second channel region.

5. The system as claimed in claim 4, wherein the length of the second channel region is smaller than a length of the first channel region.

6. The system as claimed in claim 4, wherein the bottom width of the second gate electrode is larger than a bottom width of the first gate electrode.

7. The system as claimed in claim 3, wherein the first active layer, the gate insulating layer, and the first dielectric layer and the first gate electrode compose a switch device, comprising an N-type metal-oxide-semiconductor (NMOS) device.

8. The system as claimed in claim 3, wherein the second active layer, the gate insulating layer, the second dielectric layer and the second gate electrode compose a switch device, comprising a P-type metal-oxide-semiconductor (PMOS) device.

9. The system as claimed in claim 1, wherein the extending portion of the first dielectric layer has a length of between 3000 to 4000 angstrom (Å).

10. The system as claimed in claim 1, further comprising:
a display panel comprising the low-temperature polysilicon driving circuit and the thin film transistor; and
a control unit coupled with the display panel for control thereto.

11. The system as claimed in claim 10, wherein the system comprises an electronic device using the display panel.

12. The system as claimed in claim 11, wherein the electronic device comprises mobile phones, digital cameras, personal digital assistants (PDA), notebook computers, desktop computers, televisions (TV), automotive monitors, global positioning systems, avionics display or portable digital video disc (DVD) players.

13. A method for fabricating an image display system, comprising:
fabricating a low-temperature polysilicon driving circuit and thin film transistor, comprising:
providing a substrate;
forming a first active layer and a second active layer over the substrate;
depositing a dielectric material layer over the substrate;
depositing a metal layer on the dielectric material layer;
patterning the metal layer to respectively form a first gate electrode and a second gate electrode on the first active layer and the second active layer, and simultaneously forming a dielectric layer having an extending portion between the first gate electrode and the first active layer; and
performing a first doping process to simultaneously form a lightly doped source/drain region and a first source/drain region in the first active layer;
forming a plurality of wiring lines over the substrate to electrically connect the driving circuit to the thin film transistor; and
forming a pixel electrode over the substrate, electrically connected to the thin film transistor.

14. The method as claimed in claim 13, wherein the first active layer and the second active layer are formed by the steps, comprising:
depositing an amorphous silicon layer on the substrate;
performing a laser annealing treatment to crystallize the amorphous silicon layer into a polysilicon layer;
patterning the polysilicon layer; and
performing a second doping process to form the first active layer and the second active layer.

15. The method as claimed in claim 13, wherein the metal layer is patterned by the steps, comprising:
forming a patterned photoresist layer on the metal layer;
removing a portion of the metal layer and the dielectric material layer by an over etching process to form the first gate electrode, the second gate electrode and the dielectric layer having the extending portion; and
removing the patterned photoresist layer.

16. The method as claimed in claim 13, wherein after the first doping process is performed, the method further comprises:
forming a photoresist material over the substrate;
patterning the photoresist material to expose the second gate electrode and the second active layer;
performing a second doping process to form a second source/drain region; and
removing the patterned photoresist material.

17. The method as claimed in claim 13, wherein before the metal layer is deposited, the method further comprises:
forming a photoresist material over the substrate;
patterning the photoresist material to expose a portion of the second active layer;
performing a second doping process to form a channel region and a second source/drain region, in which the second gate electrode has a bottom width large than the length of the channel region; and
removing the patterned photoresist material.

18. The method as claimed in claim 13, further comprising forming a storage capacity device having an upper electrode and a lower electrode on the substrate.

19. The method as claimed in claim 18, wherein before the wiring lines are formed, the method further comprises:
forming a passivation layer over the substrate, covering the driving circuit, the thin film transistor and the storage capacity device; and
patterning the passivation layer to form a contact hole exposing a region where the lower electrode is adjacent to the first source/drain region of the thin film transistor.

20. The method as claimed in claim 13, wherein before the pixel electrode is formed, the method further comprises:
forming an overcoating layer over the substrate; and
patterning the overcoating layer to form an opening therein.
